(19) United States
(12) Patent Application Publication
(10) Pub. No.: US 2026/0052776 A1
(43) Pub. Date: Feb. 19, 2026

(54) DISPLAY APPARATUS AND MANUFACTURING METHOD THEREOF

(71) Applicant: Peking University Shenzhen Graduate School, Shenzhen P.R. (CN)

(72) Inventors: Shengdong Zhang, Shenzhen P.R. (CN); Yuhan Zhang, Shenzhen P.R. (CN); Congwei Liao, Shenzhen P.R. (CN); Tengyan Huang, Shenzhen P.R. (CN); Jiangbo Hu, Shenzhen P.R. (CN)

(21) Appl. No.: 19/002,340

(22) Filed: Dec. 26, 2024

(30) Foreign Application Priority Data
Aug. 15, 2024 (CN) 2024111278739

(51) Int. Cl. H10D 86/80; H10D 86/01; H10D 86/40

(52) U.S. Cl. CPC H10D 86/80; H10D 86/0221; H10D 86/423; H10D 86/441

(57) ABSTRACT

The present application discloses a display apparatus comprising a pixel array, wherein at least one pixel comprises a first transistor and a second transistor formed on the same substrate and uniformly manufactured using the same process, both comprising a substrate; a light shielding layer located on the substrate; a first dielectric layer located on the light shielding layer; an active layer located on the first dielectric layer, and source and drain regions located at two ends of the active layer; a second dielectric layer located on the active layer; a top electrode located on the second dielectric layer; a passivation layer comprising a via located above the top electrode, the active layer and the first dielectric layer; the first capacitance between the light shielding layer and the active layer and the second capacitance between the active layer and the top electrode are different.

### CROSS-REFERENCE TO RELATED APPLICATIONS

The present application claims priority to Chinese Patent Application No. 2024111278739 titled “Display Apparatus and Manufacturing Method Thereof” and filed Aug. 15, 2024, the entirety of which is incorporated by reference hereto.

### TECHNICAL FIELD

Aspects of the present application relate to the field of semiconductor, and more particularly, to a display apparatus and a manufacturing method thereof.

### BACKGROUND

Currently commercialized mainstream TFT technology includes hydrogenated amorphous silicon (a-Si:H) TFT, low temperature polysilicon (LTPS) TFT, and metal oxide (MO) TFT. A-Si:H TFT process is mature, low cost and good uniformity in large area, but limited by amorphous structure, its mobility is very low. In contrast, LTPS TFT has a high mobility but is limited by grain boundary defects and has poor large area uniformity. MO TFT has high mobility, good large area uniformity, low production cost and high commercial value.

On the other hand, with advances in display technology, the OLED energy conversion efficiency continues to increase and the drive current required for light-emitting elements continues to decrease. A MO TFT (Metal Oxide Thin Film Transistor) backplane can well meet the drive current requirements of a display pixel. However, for high resolution displays, this makes greyscale control of the pixel circuit difficult as the drive transistor operates in the sub-threshold region when the drive current is small. This is due to the fact that the subthreshold region transistor current varies exponentially with the gate voltage, and when the subthreshold swing (SS) of the drive transistor is too small, the data voltage varies over a small range for a full amplitude drive current.

It can be seen therefrom that with regard to the AMOLED display using the MO TFT, the driving accuracy of the existing driving IC technology is insufficient, and it is difficult to divide a small data voltage range into a plurality of different grey levels, so it is difficult to realize a high-grey-level AMOLED display.

### SUMMARY

In order to solve the above-mentioned technical problem, the present application provides a display apparatus, comprising a pixel array, and a source driving circuit and a gate driving circuit coupled to the pixel array; wherein at least one pixel in the pixel array comprises a first transistor and a second transistor formed on a same substrate and manufactured using the same process; wherein the first transistor and the second transistor both comprise, the substrate; a light shielding layer comprising a first conductive layer located on the substrate; a first dielectric layer located on the light shielding layer; an active layer comprising a first semiconductor layer located on the first dielectric layer, and source and drain regions located at two ends of the active layer; a second dielectric layer located on the active layer; a top electrode comprising a second conductive layer located on the second dielectric layer; a passivation layer including vias located above the top electrode, the active layer and the first dielectric layer; wherein a first capacitance formed between the light shielding layer and the active layer and a second capacitance formed between the active layer and the top electrode are different in value; and when the first capacitance is smaller than the second capacitance, the light shielding layer in the first transistor is configured as a control electrode to receive data signals, and the top electrode thereof is configured as a bias electrode to receive bias signals; when the first capacitance is larger than the second capacitance, the top electrode in the first transistor is configured as a control electrode to receive data signals, and the light shielding layer is configured as a bias electrode.

Specifically, when the first capacitance is smaller than the second capacitance, the light shielding layer in the second transistor is configured as a bias electrode to receive bias signals, and the top electrode of the second transistor is configured as a control electrode; when the first capacitance is larger than the second capacitance, the top electrode in the second transistor is configured as a bias electrode to receive bias signa, and the light shielding layer of the second transistor is configured as a control electrode.

Specifically, the light shielding layer in the second transistor is electrically connected to its top electrode and the light shielding layer are jointly configured as a control electrode of the second transistor.

Specifically, the first transistor is a driving transistor, the second transistor is a switching transistor.

Specifically, the first semiconductor layer comprises metal oxide semiconductor.

Specifically, the second capacitance is 2-4 times of the first capacitance.

Specifically, thickness of the first dielectric layer and thickness of the second dielectric layer are different, but dielectric constants of the two layers are the same; or, thickness of the first dielectric layer and thickness of the second dielectric layer are the same, but dielectric constant of the first dielectric layer and dielectric constant of the second dielectric layer are different; or, thickness of the first dielectric layer and thickness of the second dielectric layer are different, and their dielectric constants are also different.

Specifically, the metal oxide semiconductor comprises one or more of IGZO, IZO, IGO, In₂O₃, ZTO, and ITZO.

Specifically, the first dielectric layer and/or the second dielectric layer comprises one or more of silicon oxide, silicon nitride, aluminum oxide, hafnium oxide.

Specifically, the thickness range of the first dielectric layer and/or the second dielectric layer is from 1000 Å to 6000 Å.

The present application also provides a method of manufacturing method of a display apparatus, comprising forming a first conductive layer on a substrate, and patterning the first conductive layer to form light shielding layers which are separated from each other; forming a first dielectric layer on the substrate and the light shielding layer; forming a first semiconductor layer on the first dielectric layer and patterning the first semiconductor layer to obtain separated active layers, and removing the active layer above part of the light shielding layers; forming a second dielectric layer on the active layer and the first dielectric layer; forming a second conductive layer on the second dielectric layer; patterning the second conductive layer and the second dielectric layer so as to form separated top electrode layers and second dielectric layers, and removing the second conductive layer and the second dielectric layer above the part of the light shielding layers; using the separated top electrode layers and second dielectric layers as a mask to form a source region and a drain region in the active layer located at either side of the top electrode layers; forming a passivation layer on the top electrode layers, the active layers and the first dielectric layer; wherein, a first capacitance formed between the light shielding layer and the active layer and a second capacitance formed between the active layer and the top electrode layer are different in value; when the first capacitance is smaller than the second capacitance, the light shielding layer in the first transistor is configured as a control electrode to receive data signals, and the top electrode layer thereof is configured as a bias electrode to receive bias signals; when the first capacitance is larger than the second capacitance, the top electrode layer in the first transistor is configured as a control electrode to receive data signals, and the light shielding layer is configured as a bias electrode to receive bias signals.

Specifically, the method further comprising forming vias in the passivation layer, and respectively forming above the passivation layer a first portion of a third conductive layer electrically connected to the top electrode layers, a second portion of the third conductive layer electrically connected to the source regions, and a third portion of the third conductive layer electrically connected to the light shielding layers; patterning the third conductive layer to electrically isolate the first portion, the second portion, and the third portion of the third conductive layer in the first transistor.

Specifically, patterning the third conductive layer comprises maintaining the electrical connection between the first portion and the third portion of the third conductive layer in the second transistor.

Specifically, when the first capacitance is smaller than the second capacitance, patterning the third conductive layer comprises, maintaining the electrical connection between the second portion and the third portion of the third conductive layer in the second transistor; when the first capacitance is larger than the second capacitance, patterning the third conductive layer comprises, maintaining the electrical connection of between the second portion and the first portion of the third conductive layer in the second transistor.

Specifically, the first transistor is a driving transistor, the second transistor is a switching transistor.

Specifically, the first semiconductor layer comprises a metal oxide semiconductor, including one or more of IGZO, IZO, IGO, In₂O₃, ZTO, ITZO.

Specifically, the first dielectric layer and/or the second dielectric layer comprises one or more of silicon oxide, silicon nitride, aluminum oxide, hafnium oxide.

The present application also provides another display apparatus, comprising a pixel array, and a source driving circuit and a gate driving circuit coupled to the pixel array; wherein at least one pixel in said the pixel array comprises a third transistor and a fourth transistor formed on a same substrate and uniformly manufactured using the same process; wherein the third transistor and the fourth transistor both comprise, the substrate; a bottom electrode comprising a fourth conductive layer located on the substrate; a third dielectric layer located on the bottom electrode; an active layer comprising a second semiconductor layer located on the third dielectric layer, and a source region and a drain region located at two ends in the active layer; a source electrode and a drain electrode comprising a fifth conductive layer which are respectively electrically connected to the source region and the drain region and are located on the active layer and the third dielectric layer; a fourth dielectric layer comprising vias located on the active layer, the source electrode and the drain electrode and the third dielectric layer; a light shielding layer located on the fourth dielectric layer and at least located above the active layer, comprising a sixth conductive layer; wherein a third capacitance formed between the sixth conductive layer and the active layer and a fourth capacitance formed between the active layer and the bottom electrode are different in value; when the third capacitance is smaller than the fourth capacitance, the light shielding layer in the third transistor is configured as a control electrode to receive data signals, and the bottom electrode thereof is configured as a bias electrode to receive bias signals; when the third capacitance is larger than the fourth capacitance, the bottom electrode in the third transistor is configured as a control electrode to receive data signals, and the light shielding layer is configured as a bias electrode to receive bias signals.

Specifically, when the third capacitance is smaller than the fourth capacitance, the light shielding layer in the fourth transistor is configured as a bias electrode to receive bias signals, and the bottom electrode is configured as a control electrode; when the third capacitance is larger than the fourth capacitance, the bottom electrode in the fourth transistor is configured as a bias electrode to receive bias signals, and the light shielding layer is configured as a control electrode.

Specifically, the light shielding layer of the fourth transistor is electrically connected to the bottom electrode are jointly configured as a control electrode of the second transistor.

Specifically, the third transistor is a driving transistor, the fourth transistor is a switching transistor.

Specifically, the second semiconductor layer comprises metal oxide semiconductor.

Specifically, the fourth capacitance is 2-4 times of the third capacitance.

Specifically, the thickness of the third dielectric layer and the thickness of the fourth dielectric layer are different, but the dielectric constants of the two layers are the same; or, the thickness of the third dielectric layer and the thickness of the fourth dielectric layer are the same, but the dielectric constant of the third dielectric layer and the dielectric constant of the fourth dielectric layer are different; or, the thickness of the third dielectric layer and the thickness of the fourth dielectric layer are different, and the dielectric constants are also different.

Specifically, the metal oxide semiconductor comprises one or more of IGZO, IZO, IGO, In₂O₃, ZTO, and ITZO.

Specifically, the third dielectric layer and/or the fourth dielectric layer comprises one or more of silicon oxide, silicon nitride, aluminum oxide, hafnium oxide.

Specifically, the thickness range of the third dielectric layer and/or the fourth dielectric layer is from 1000 Å to 6000 Å.

The present application also provides another manufacturing method of a display apparatus, comprising forming a fourth conductive layer on a substrate, and patterning the fourth conductive layer to form separated bottom electrode layers; forming a third dielectric layer on the substrate and the bottom electrode layers, and forming first vias in the third dielectric layer on some of the bottom electrode layers to expose a part of such bottom electrode layers; forming a second semiconductor layer on the third dielectric layer, patterning the second semiconductor layer to form separated active layers which are doped to form source regions and drain regions, and removing the active layer in the first vias to expose the part of the bottom electrode layers; forming a fifth conductive layer on the active layer, and patterning the fifth conductive layer, forming a source electrode layer and a drain electrode layer that are respectively and electrically connected with the source regions and the drain regions in the active layer; forming a fourth dielectric layer on the active layer, the source electrode layer, the drain electrode layer and the third dielectric layer; etching the fourth dielectric layer to form second vias exposing the source electrode layer, and removing the fourth dielectric layer in the first vias to expose a part of the bottom electrode layers; forming a sixth conductive layer at least located above the active layer on the fourth dielectric layer; patterning the sixth conductive layer to form separated light shielding layers, wherein the light shielding layers electrically connected to the source electrode layers through the second vias, the light shielding layers electrically connected to the bottom electrode layers through the first vias, and the rest light shielding layers are separated; wherein, a third capacitance formed between the light shielding layers and the active layers and a fourth capacitance formed between the active layers and the bottom electrode layers are different in value; when the third capacitance is smaller than the fourth capacitance, the light shielding layer in a third transistor is configured as a control electrode to receive data signals, and the bottom electrode thereof is configured as a bias electrode to receive bias signals; when the third capacitance is larger than the fourth capacitance, the bottom electrode in a third transistor is configured as a control electrode to receive data signals, and the light shielding layer is configured as a bias electrode to receive bias signals.

Specifically, patterning the sixth conductive layer comprises respectively forming a first portion of the sixth conductive layer electrically connected to the bottom electrode layers through the first via, a second portion of the sixth conductive layer electrically connected to the source electrode layers through the second via, and a third portion of the sixth conductive layer electrically isolated from both the bottom electrode layers and the source and drain electrode layers; the light shielding layer in a third transistor is the third portion of the sixth conductive layer.

Specifically, when the third capacitance is smaller than the fourth capacitance, patterning the sixth conductive layer comprises, the light shielding layer in a fourth transistor being the second portion of the sixth conductive layer; when the third capacitance is larger than the fourth capacitance, electrically connecting the bottom electrode layer of the second transistor to the source electrode layer.

Specifically, the light shielding layer in the second transistor is the first portion of the sixth conductive layer.

Specifically, the second semiconductor layer comprises a metal oxide semiconductor, including one or more of IGZO, IZO, IGO, In₂O₃, ZTO, ITZO.

Specifically, the third dielectric layer and/or the fourth dielectric layer comprises one or more of silicon oxide, silicon nitride, aluminum oxide, hafnium oxide.

The solution provided by the present application can enable transistors in a circuit manufactured under the same process flow to have different subthreshold swings, simultaneously meeting different performance requirements of transistors with different functions in the circuit, improving process compatibility, and reducing production costs.

### BRIEF DESCRIPTION OF THE DRAWINGS

Hereinafter, embodiments of the present application will be described in further detail with reference to the accompanying drawings, wherein:

FIGS. 1a-1h are schematic diagrams of part of a process state of a method of manufacturing a display apparatus according to an embodiment of the present application;

FIG. 2a is a schematic layout diagram illustrating a switching transistor in which a top electrode serves as a control electrode, a light shielding layer and a source electrode are electrically connected in a display apparatus according to an embodiment of the present application;

FIG. 2b is a schematic layout diagram illustrating the structure of a switching transistor in which a light shielding layer and a top electrode are electrically connected as a control electrode in a display apparatus according to an embodiment of the present application;

FIG. 2c is a schematic layout diagram illustrating the structure of a driving transistor in which a light shielding layer serves as a control electrode electrically isolated from each of a top electrode, a source electrode and a drain electrode in a display apparatus according to an embodiment of the present application;

FIGS. 3a-3f are schematic diagrams of part of a process state of a method of manufacturing a display apparatus according to another embodiment of the present application;

FIG. 4a is a layout illustrating a switching transistor in which a bottom electrode serves as a control electrode, a light shielding layer and a source electrode are electrically connected in a display apparatus according to an embodiment of the present application;

FIG. 4b is a schematic layout diagram illustrating a switching transistor in which a bottom electrode and a light shielding layer are electrically connected as a control electrode in the display apparatus according to an embodiment of the present application;

FIG. 4c is a schematic layout diagram illustrating a driving transistor in which a light shielding layer serves as a control electrode electrically isolated from each of a bottom electrode, a source electrode and a drain electrode in a display apparatus according to an embodiment of the present application.

FIG. 5 is a schematic diagram of a portion of a layout illustrating a display apparatus according to an embodiment of the present application; and

FIG. 6 is a schematic diagram illustrating the characteristics of the gate voltage versus source drain current curves for different transistors in a display apparatus according to an embodiment of the present application.

### DESCRIPTION OF DISCLOSURE

For the purposes, technical solutions and advantages of the embodiments of the present application to become clearer, the technical solutions in the embodiments of the present application will be clearly and completely described in conjunction with the accompanying drawings in the embodiments of the present application, and it is obvious that the described embodiments are a part of the embodiments of the present application rather than all the embodiments. Based on the embodiments in the present application, all the other embodiments obtained by a person of ordinary skill in the art without making any inventive effort fall within the scope of protection of the present application.

In AMOLED pixel circuits, in general, the smaller the subthreshold swing of the switching transistor, the better, the circuit response speed can be improved and the power consumption can be reduced; the driving transistor in the pixel requires a relatively larger subthreshold swing to extend the data voltage range to facilitate high gray levels. In the prior art, in an integrated circuit manufactured under the same process, each transistor has an identical structure, and the dielectric layer thickness and dielectric constant are all the same, so the subthreshold swing of each transistor is basically the same, which cannot meet the performance requirements of different devices of different functional transistors in an AMOLED pixel circuit. Currently, existing solutions typically compensate for the problem of too narrow data voltage range due to too small a subthreshold swing by adjusting the design of the pixel circuit and the source or gate driving circuit.

There has not been a low-cost solution prior to the present application that does not require adjustments to the circuit design to meet both the requirement that the subthreshold swing of the pixel driving transistor not be too small and the expectation that the smaller the subthreshold swing of the switching transistor will be better.

The present application proposes a solution to solve the above seemingly contradictory requirements, and a display apparatus comprising transistors with different subthreshold characteristics can be manufactured uniformly without changing the circuit design and without using different manufacturing processes.

In existing AMOLED pixel circuits, the light shielding layer is an opaque material used to protect the semiconductor channel from light. Generally, the light shielding layer is located below the active layer of the transistor, and the gate electrode is located above the active layer of the transistor; of course, in some transistors, it is also possible that the light shielding layer is located above the active layer and the gate electrode is located below the active layer of the transistor.

Generally, a non-transparent metal material is used for the light shielding layer. Other non-metallic materials that are opaque to light do not work well as light shielding layers for a variety of reasons, e.g. their thickness is often not as thin.

In order to avoid unwanted electrical effects of the light shielding layer on the active layer or the channel, such as coupling effects, the light shielding layer at the bottom of the transistor is usually connected to the source or drain of the transistor.

Due to the shielding responsibility of the existing light shielding layer, the size, thickness, area and other properties of the existing light shielding layer are often different from those of the gate electrode. Therefore, prior to the present application, based on the present situation, the cognition of a light shielding layer still remains at a relatively single role and design level.

Prior to the present application, there was no solution of using a light shielding layer as a control electrode to control the operating state of a transistor in a pixel. Instead, technical measures are often taken to avoid any electrical influence of the light shielding layer on the channel. However, in the present application, the problem that a data voltage range is too narrow due to too small sub-threshold swing of a transistor in a pixel circuit such as AMOLED is solved by skillfully multiplexing a light shielding layer.

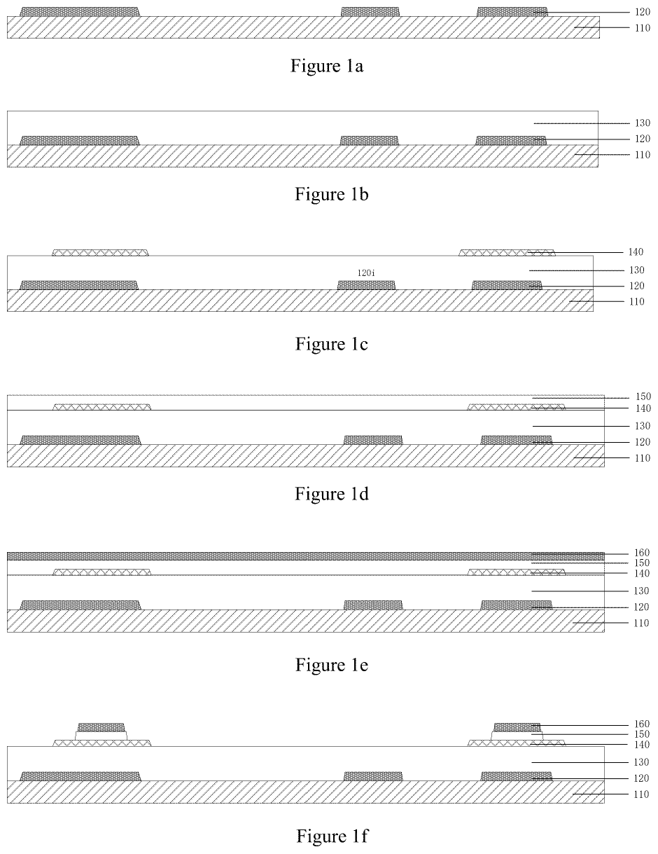

FIGS. 1a-1h are schematic diagram of part of a process state of a method of manufacturing an AMOLED display apparatus according to an embodiment of the present application.

At 1001, as shown in FIG. 1a, a first conductive layer is formed on a substrate 110 and patterned to form a light shielding layer 120 that is separated from one another.

According to various embodiments, the substrate 110 may be a rigid material such as silicon, glass or the like, or a flexible material such as PI, PET or the like. The material of the first conductive layer may comprise a conductive material such as molybdenum, copper, a molybdenum titanium alloy or the like, or a stack comprising the above materials. According to an embodiment, the thickness range of the conductive material in the light shielding layer includes, but is not limited to, 1000 Å to 5000 Å.

At 1002, as shown in FIG. 1b, a first dielectric layer 130 is formed on the substrate 110 and the light shielding layer 120.

According to various embodiments, the first dielectric layer 130 may comprise an insulating material, such as silicon oxide, silicon nitride, aluminum oxide, hafnium oxide, or the like, or a stack comprising several of the above materials, with a thickness range including, but not limited to, 1000 Å to 6000 Å.

At 1003, as shown in FIG. 1c, a first semiconductor layer is formed on the first dielectric layer 130 and patterned to form active layers 140 of the transistor that are separated from one another. According to an embodiment, during the patterning of the first semiconductor layer, portions of the active layer 140 above the light shielding layer 120i are removed.

According to various embodiments, the first semiconductor active layer may comprise a metal oxide semiconductor, such as IGZO, IZO, IGO, In₂O₃, ZTO, ITZO, etc. with a thickness range including, but not limited to, 100 Å to 1000 Å.

At 1004, as shown in FIG. 1d, a second dielectric layer 150 is formed on the active layer 140 and the first dielectric layer 130.

According to various embodiments, the second dielectric layer 150 comprises an insulating material, such as silicon oxide, silicon nitride, aluminum oxide, hafnium oxide, etc. or a stack comprising several of the above materials, with a thickness range including, but not limited to, 1000 Å to 6000 Å.

According to an embodiment, the second dielectric layer 150 may be formed directly on the first dielectric layer 130 in a region where the light shielding layer 120i is formed but no active layer 140 above it.

At 1005, as shown in FIG. 1e, a second conductive layer is formed is formed on the second dielectric layer 150.

According to various embodiments, the material of the second conductive layer may comprise a material such as molybdenum, copper, ITO, molybdenum titanium alloy, or the like, or a stack combination of the above materials, with a thickness range including, but not limited to, 1000 Å to 6000 Å.

According to an embodiment, the second conductive layer is formed directly on the second dielectric layer 150 in a region where the light shielding layer 120i is formed but no active layer above it.

At 1006, as shown in FIG. 1f, the second conductive layer and the second dielectric layer 150 are patterned with the same mask, removing the second dielectric layer between the active layers, thereby forming separated top electrode layers 160 and corresponding separated second dielectric layers 150.

According to an embodiment, the second dielectric layer and the second conductive layer above the light shielding layer 120i may be removed in a region where the light shielding layer 120i is formed but no active layer above it, thereby exposing a portion of the surface of the first dielectric layer 130.

At 1007, using the separated top electrode layer 160 and the second dielectric layer 150 as a mask, a plasma (such as Ar) bombardment treatment, a hydrogen (H) doping treatment, a metal reaction treatment, etc. are used to reduce the resistance of the active layer which is not covered, so as to form a self-aligned and highly conductive source and drain region in the active layer.

According to other embodiments, non-self-aligned structures may also be formed by other existing process means.

According to various embodiments, the dielectric constant of the first dielectric layer and the second dielectric layer may be the same, but the thickness may be different; the thickness may be the same, and the dielectric constant may be different; alternatively, both the dielectric constant and the thickness may be different, so that the capacitance C1 formed by the active layer 140, the second dielectric layer 150 and the top electrode 160 may differ significantly from the capacitance C2 formed by the light shielding layer 120, the first dielectric layer 130 and the active layer 140, in particular C2 may be smaller than C1, e.g. C1 is 2-4 times, e.g. 3 times C2. For example, in case the materials of the first dielectric layer 130 and the second dielectric layer 150 are the same, the thickness of the first dielectric layer 130 may be 2-4 times, e.g. 3 times that of the second dielectric layer 150. In this case, the light shielding layer can serve as a control electrode of the driving transistor to receive a data signal, and the top electrode serves as a bias electrode, which is biased at a certain potential and is determined by a specific circuit; also, for a switching transistor on the same substrate, the top electrode may serve as its control electrode, and the light shielding layer serves as a bias electrode.

Of course, according to another embodiment, if C2 is greater than C1, the top electrode may serve as a control electrode of the driving transistor to receive a data signal, and the light shielding layer serves as a bias electrode to receive a bias signal; in this case, the switching transistor may employ the light shielding layer as a control electrode, and the top electrode as a bias electrode to receive a bias signal.

At 1008, as shown in FIG. 1g, a passivation layer 170 is formed on the top electrode layer 160, the active layer 140, and the first dielectric layer 130.

Wherein the passivation layer 170 may be an inorganic material such as silicon oxide, silicon nitride, aluminum oxide and hafnium oxide, or the like, and may also be an organic material such as Parylene, CYTOP and Teflon, or the like.

According to an embodiment, the passivation layer 170 is formed directly on the first dielectric layer 130 in a region where the light shielding layer 120i is formed but no active layer above it.

At 1009, as shown in FIG. 1h, the passivation layer 170 is patterned and etched to form vias. A third conductive layer 180 is formed on the passivation layer 170 and in the vias and patterned to form different electrical connections.

According to an embodiment, in the leftmost switching transistor structure 11, a via passing through the passivation layer 170 so as to expose the source electrode region of the active layer, a via passing through the passivation layer 170 so as to expose the surface of the top electrode layer 160, and a via passing through the passivation layer 170 and the first dielectric layer 130 so as to expose the light shielding layer 120 are respectively formed, and the third conductive layer material 180 is filled in the vias; wherein, the third conductive layer 180a electrically connecting the top electrode layer 160 is disconnected from the other portion of the third conductive layer, and the third conductive layers 180b and 180i electrically connecting the light shielding layer 120a and the source electrode are kept being in connection with each other.

According to an embodiment, the rightmost structure 12, which may be a driving transistor structure, may also be a cross-section view of a switching transistor with the top electrode electrically connected to the light shielding layer. For a driving transistor, only forming a via passing through the passivation layer 170 to expose the top electrode layer and the source or drain region of the active region, and filling the third conductive layers 180a and 180b therein, and the two being disconnected from each other; and forming a via passing through the passivation layer 170 and the first dielectric layer 130 to expose the light shielding layer 120i in a region where the light shielding layer 120i is formed but no active region above it, and filling the third conductive layer 180i therein, which is electrically isolated from the other third conductive layers 180a, 180b; for a switching transistor, the third conductive layer 180i may be electrically connected to the third conductive layer 180a (not shown).

According to an embodiment, the third conductive layer 180 may be a metallic material such as molybdenum, copper, ITO, molybdenum titanium alloy, or a stack combination of the above materials.

The above example of electrode extraction using the third conductive layer is merely an embodiment for illustration, according to other embodiments, if the signals received by each of the electrodes in the transistor are not internal to the pixel, but external signals, electrical connections may be made directly by wires at the periphery of the array, so that the third conductive layer may not be provided within the pixel.

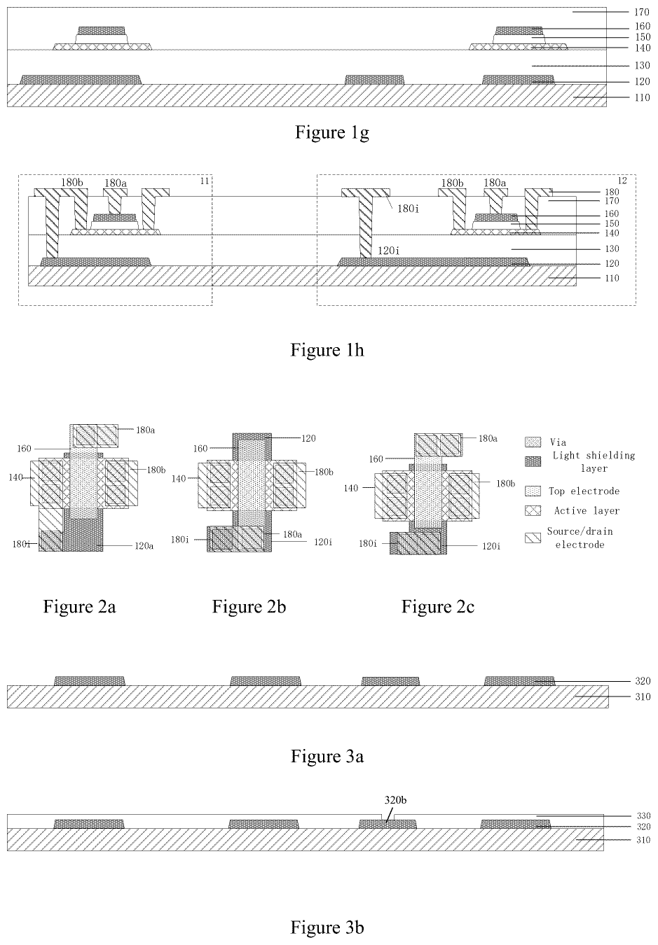

FIG. 2a is a layout diagram illustrating a switching transistor in an AMOLED display apparatus according to an embodiment of the present application, in which the light shielding layer is electrically connected to the third conductive layer 180i, the third conductive layer 180b is electrically connected to the source electrode, and the third conductive layer 180i and the third conductive layer 180b are electrically connected to each other.

FIG. 2b is a layout diagram illustrating the structure of a switching transistor in an AMOLED display apparatus according to an embodiment of the present application, in which the light shielding layer is electrically connected to the third conductive layer 180i, the third conductive layer 180a is electrically connected to the top electrode, and third conductive layer 180i and the third conductive layer 180a are electrically connected to each other.

FIG. 2c is a layout diagram illustrating the structure of a driving transistor in an AMOLED display apparatus according to an embodiment of the present application, in which the light shielding layer is electrically connected to the third conductive layer 180i, the third conductive layer 180a electrically connected to the top electrode and the third conductive layer 180b electrically connected to the source electrode, the third conductive layer 180i are electrically isolated from the third conductive layer 180a and the third conductive layer 180b.

According to an embodiment, in an AMOLED display apparatus, the driving transistor in the pixel may adopt the structure shown in FIG. 2c, with the light shielding layer 120i serving as a control electrode to control the operation of the driving transistor, and the top electrode 160 serving as a bias electrode electrically connected to a node in the circuit (depending on the particular pixel circuit) or receiving a certain bias signal, e.g. ground level. Since the capacitance C1 formed by the active layer, the second dielectric layer 150 and the top electrode is significantly different from the capacitance C2 formed by the light shielding layer, the first dielectric layer 130 and the active layer, in particular C2 is smaller than C1, in the case of using the light shielding layer as a control electrode, the subthreshold swing of the driving transistor is significantly greater than that in the case of using the top electrode as a control electrode, thereby widening the data voltage range in which the driving transistor can operate.

According to an embodiment, in an AMOLED display apparatus, the switching transistor may adopt the structure shown in FIG. 2a, using the top electrode as the control electrode of the channel, and its light shielding layer may be electrically connected to the source electrode, avoiding unnecessary electrical influence of the light shielding layer on the channel.

According to an embodiment, in an AMOLED display apparatus, the switching transistor may also adopt the structure shown in FIG. 2b, the light shielding layer and the top electrode are electrically connected together as a control electrode to jointly control the channel, and the subthreshold swing of this type of transistor structure is smaller than that of the transistor structure shown in FIG. 2a, and the switching state of the switching transistor can be controlled more efficiently.

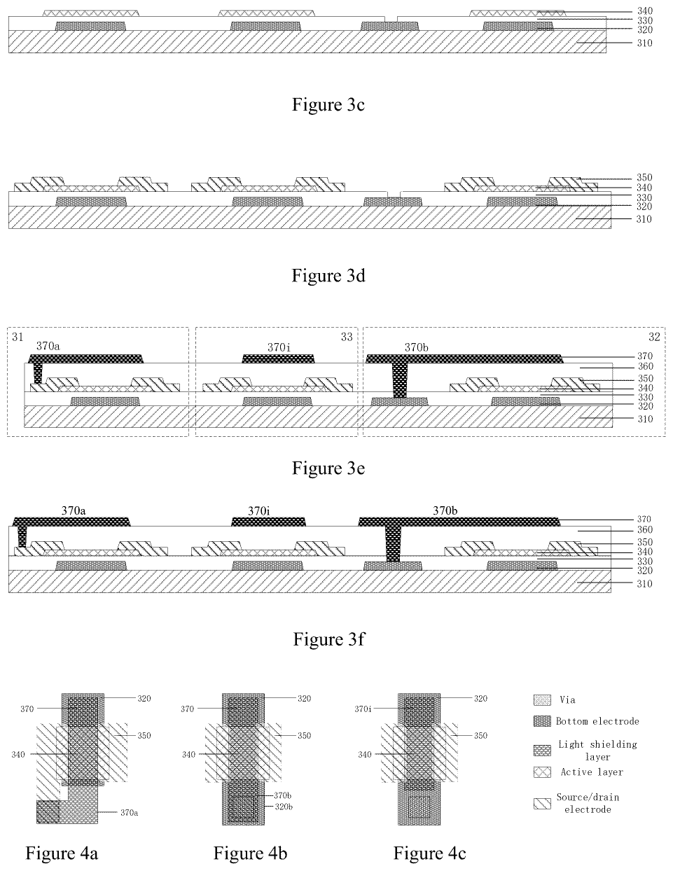

FIGS. 3a-3f are schematic diagrams of part of a process state of a method of manufacturing an AMOLED display apparatus according to an embodiment of the present application.

At 3001, as shown in FIG. 3a, a fourth conductive layer is formed on a substrate 310 and patterned to form a bottom electrode 320.

According to various embodiments, the substrate 310 may comprise a rigid material such as silicon, glass, etc. or may comprise a flexible material such as PI, PET, etc. The material of the bottom electrode 320 may comprise a metal, such as molybdenum, copper, ITO, molybdenum-titanium alloys, and the like, or a stack combination of the above materials, with a thickness range including, but not limited to, 1000 Å to 5000 Å.

At 3002, as shown in FIG. 3b, a third dielectric layer 330 is formed on the substrate 310 and the bottom electrode 320. According to an embodiment, the dielectric layer 330 above a portion of the bottom electrode 320b is patterned to form a via.

According to various embodiments, the third dielectric layer 330 may comprise an insulating material, such as silicon oxide, silicon nitride, aluminum oxide, hafnium oxide, or the like, or a stack combination comprising several of the above materials, with a thickness range including, but not limited to, 1000 Å to 6000 Å.

At 3003, as shown in FIG. 3c, a second semiconductor layer is formed on the third dielectric layer 330 and patterned to form an active layers 340 of the transistor that are separated from one another above a portion of the bottom electrode 320. According to various embodiments, the second semiconductor layer in and above the via on the bottom electrode 320b is removed to expose a portion of the surface of the bottom electrode 320b.

According to various embodiments, the active layer 340 may comprise a metal oxide semiconductor, such as IGZO, IZO, IGO, In₂O₃, ZTO, ITZO, etc. with a thickness range including, but not limited to, 100 Å to 1000 Å.

At 3004, as shown in FIG. 3d, a fifth conductive layer is formed on the active layer 340 and the third dielectric layer 330, and patterned to form source and drain electrode layers 350. The material of the source and drain electrode layers 350 may comprise a material such as molybdenum, copper, ITO, molybdenum titanium alloy, or the like, or a stack combination of the above materials, with a thickness range including, but not limited to, 1000 Å to 5000 Å.

At 3005, as shown in FIG. 3e, a fourth dielectric layer 360 is formed on the third dielectric layer 330, the active layer 340, and the source drain electrode layer 350, and the fourth dielectric layer 360 is patterned to form vias. According to various embodiments, the fourth dielectric layer 360 in and above the via on the bottom electrode 320b is removed to expose a part of the surface of the bottom electrode 320b; the fourth dielectric layer 360 may also be etched to form vias that expose the surface of the source electrode layer or the drain electrode layer.

According to various embodiments, the fourth dielectric layer (the passivation layer) 360 may comprise an insulating material, such as silicon oxide, silicon nitride, aluminum oxide, hafnium oxide, etc. or a stack comprising several of the above materials, with a thickness range including but not limited to 1000 Å to 6000 Å.

At 3006, as shown in FIG. 3f, a sixth conductive layer at least partially above the active layer is formed on the dielectric layer 360, and patterned to form a light shielding layer 370.

According to an embodiment, in the switching transistor structure 31 on the left side, in addition to being located above the active layer for shielding the light, the sixth conductive layer 370a in the light shielding layer 370 may also include a portion filling the via and electrically connected to the source electrode layer 350 of the transistor. According to an embodiment, in the switching transistor structure 32 on the right side, the sixth conductive layer in the light shielding layer 370b may fill the via to electrically connect with the bottom electrode layer 320b without the active layer above it. In the driving transistor structure 33 in the middle, the light shielding layer 370i may be electrically isolated from both the bottom electrode 320 and the source electrode layer 350.

According to an embodiment, the third dielectric layer 330 and the fourth dielectric layer 360 may comprise an insulating material, such as silicon oxide, silicon nitride, aluminum oxide, hafnium oxide, etc. or a stack combination comprising several of the above materials, with a thickness range including, but not limited to, 1000 Å to 6000 Å.

According to various embodiments, the dielectric constant of the third dielectric layer and the fourth dielectric layer may be the same, but the thickness may be different; the thickness may be the same, and the dielectric constant may be different; alternatively, both the dielectric constant and the thickness may be different, so that the capacitance C3 formed by the second active layer 340, the third dielectric layer 330 and the bottom electrode layer 310 may differ significantly from the capacitance C4 formed by the light shielding layer 370, the fourth dielectric layer 360 and the active layer 340, in particular C4 may be smaller than C3, e.g. C3 is 2-4 times, e.g. 3 times, C4. For example, in case the materials of the third dielectric layer 330 and the fourth dielectric layer 360 are the same, the thickness of the fourth dielectric layer 360 may be 2-4 times, e.g. 3 times, that of the third dielectric layer 330. In this case, the light shielding layer can serve as a control electrode of the driving transistor to receive a data signal, and the bottom electrode serves as a bias electrode; in addition, with regard to a switching transistor on the same substrate, the bottom electrode can serve as its control electrode, and the light shielding layer serves as a bias electrode; or the bottom electrode and the light shielding layer are electrically connected together to jointly serve as a control electrode.

Of course, according to another embodiment, if C4 is greater than C3, then the bottom electrode can serve as a control electrode of the driving transistor to receive a data signal, and the light shielding layer serves as a bias electrode; in this case, the switching transistor may employ the light shielding layer as a control electrode and the bottom electrode as a bias electrode.

According to an embodiment, the material of the sixth conductive layer in the light shielding layer 370 may comprise a conductive material such as molybdenum, copper, ITO, molybdenum titanium alloys, or the like, or a stack comprising the above materials. According to an embodiment, the thickness range of the sixth conductive layer in the light shielding layer includes, but is not limited to, 1000 Å to 5000 Å.

FIG. 4a is a layout diagram illustrating the structure of a switching transistor in an AMOLED display apparatus according to an embodiment of the present application, in which the light shielding layer is electrically connected to the source electrode layer.

FIG. 4b is a layout diagram illustrating a switching transistor of an AMOLED display apparatus according to an embodiment of the present application, in which the light shielding layer is electrically connected to a bottom electrode 320b. Specifically, the sixth conductive layer 370b and the bottom electrode 320b are electrically connected through a via passing through the third dielectric layer 330 and the fourth dielectric layer 360.

FIG. 4c is a layout diagram illustrating a driving transistor in an AMOLED display apparatus according to an embodiment of the present application, in which a light shielding layer is electrically isolated from a bottom electrode, a source electrode layer or a drain electrode layer, and the light shielding layer 370i and the bottom electrode 320 can be separately wired and controlled independently.

According to an embodiment, in an AMOLED display apparatus, the driving transistor in the pixel may adopt the structure shown in FIG. 4c, with the light shielding layer 370i serving as a control electrode to control the operation of the driving transistor, and the bottom electrode 320 serving as a bias electrode, biased at a certain potential, depending on the particular pixel circuit, e.g. ground level. Since the capacitance C3 formed by the active layer 340, the third dielectric layer 330 and the bottom electrode 320 is significantly different from the capacitance C4 formed by the sixth conductive layer 370, the fourth dielectric layer 360 and the active layer 340, in particular C3 is greater than C4, in the case of using the light shielding layer as a control electrode, the subthreshold swing of the driving transistor is greater than that in the case of using the bottom electrode as a control electrode, thereby widening the data voltage range in which the driving transistor can operate.

According to an embodiment, in an AMOLED display apparatus, the switching transistor may adopt the structure shown in FIG. 4a, using the bottom electrode as the control electrode of the channel, and its light shielding layer may serve as a bias electrode, e.g. electrically connected to the source electrode, avoiding unnecessary electrical influence of the light shielding layer on the channel.

According to an embodiment, in an AMOLED display apparatus, the switching transistor may also adopt the structure shown in FIG. 4b, the light shielding layer and the bottom electrode are electrically connected together as a control electrode to jointly control the channel, and the subthreshold swing of this type of transistor structure is smaller than that of the transistor structure shown in FIG. 4a, and the switchover of the switching state of the switching transistor can be controlled more efficiently.

The above example of electrode extraction using the sixth conductive layer is merely an embodiment for illustration. According to other embodiments, if the signals received by each of the electrodes in the transistor are not internal to the pixel, but external signals, electrical connections may be made directly by wires at the periphery of the array.

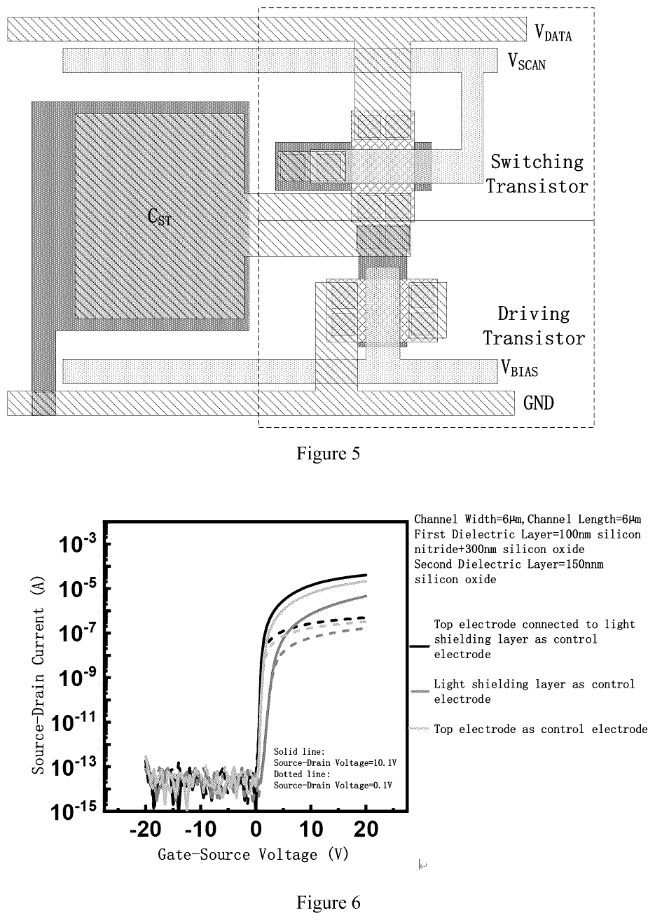

FIG. 5 is a layout diagram of a portion of an AMOLED display apparatus according to an embodiment of the present application. As shown in the figure, the light shielding layer and the top electrode layer of the switching transistor are electrically connected to each other via the conductive layer at the top, jointly serving as a control electrode of the switching transistor for receiving a scanning signal Vscan, and its drain electrode receiving a data signal Vdata; serving as the control electrode of the driving transistor, the light shielding layer of the driving transistor is electrically connected to the source electrode of the switching transistor, the top electrode of the driving transistor receives the bias voltage V_{BIAS}, and the source electrode of the driving transistor is grounded. In this embodiment, the driving transistor and the switching transistor are uniformly produced using the same manufacturing process, but the light shielding layer and the top electrode are electrically connected and jointly serve as the control electrode in the switching transistor, and the driving transistor uses the light shielding layer as the control electrode and its top electrode for receiving the bias signal. Since the capacitance between the light shielding layer and the active layer is smaller than the capacitance between the active layer and the top electrode layer, the subthreshold swing of the driving transistor using the light shielding layer as the control electrode is significantly larger than the subthreshold swing of the switching transistor using the top electrode as the control electrode. Thus, it is achieved that thin film transistors with different subthreshold swings are included in an AMOLED display apparatus which is uniformly manufactured using the same process, so as to satisfy different expectations of subthreshold properties of a switching transistor and a driving transistor respectively.

FIG. 6 is a schematic diagram illustrating the characteristics of the gate voltage versus source drain current curves for different transistors in an AMOLED display apparatus according to an embodiment of the present application. It can be seen from the thickness and material information about the first dielectric layer and the second dielectric layer shown in the figure that, the capacitance formed by the first dielectric layer, the light shielding layer and the active layer is smaller than the capacitance formed by the second dielectric layer, the active layer and the top or bottom electrode, and the smaller the capacitance is, the larger the subthreshold swing is, therefore, the transistor with the top or bottom electrode and the light shielding layer being electrically connected to jointly serve as a control electrode is of the smallest subthreshold swing, the transistor with the top or bottom electrode serving as a control electrode is of the second order, and the transistor with the light shielding layer serving as a control electrode is of the largest subthreshold swing.

The present application discloses a display apparatus comprising a display pixel array, which may comprise a switching transistor and a driving transistor as described in the previous embodiments, and may further comprise a source driving circuit and a gate driving circuit electrically connected to the display pixel array.

Although the above-mentioned embodiments in the present application are described by taking an AMOLED display apparatus and a metal oxide as an active layer as an example, but the method of the present application can be applied as long as there are situations where different transistors in the same circuit have opposite or different requirements for subthreshold swing properties from each other, and is not limited to AMOLED and metal oxide related schemes.

In addition, although in the above-mentioned embodiments the driving transistor and the display transistor are taken as examples where different transistors in the same circuit have opposite or different requirements for the subthreshold swing properties from each other, the solution in the present application is not limited to application in these two types of transistors or circuits. In the case of having similar requirements, the solution of the present application is applicable for circuits with conflicting or different requirements for transistor subthreshold swing from each other.

While the above-mentioned embodiments are merely for purposes of illustration and description of the present application, and not for limiting the present invention, it will be apparent to those skilled in the art that various changes and modifications may be made without departing from the scope of the present invention, accordingly, it is intended to embrace all such equivalents that fall within the scope of the present invention.

What is claimed is:

1. A display apparatus, comprising a pixel array, and a source driving circuit and a gate driving circuit coupled to the pixel array; wherein at least one pixel in the pixel array comprises a first transistor and a second transistor formed on a same substrate and manufactured using the same process;
wherein the first transistor and the second transistor both comprise, the substrate;
a light shielding layer comprising a first conductive layer located on the substrate;
a first dielectric layer located on the light shielding layer;
an active layer comprising a first semiconductor layer located on the first dielectric layer, and source and drain regions located at two ends of the active layer;
a second dielectric layer located on the active layer;
a top electrode comprising a second conductive layer located on the second dielectric layer;
a passivation layer including vias located above the top electrode, the active layer and the first dielectric layer;
wherein a first capacitance formed between the light shielding layer and the active layer and a second capacitance formed between the active layer and the top electrode are different in value; and
when the first capacitance is smaller than the second capacitance, the light shielding layer in the first transistor is configured as a control electrode to receive data signals, and the top electrode thereof is configured as a bias electrode to receive bias signals; when the first capacitance is larger than the second capacitance, the top electrode in the first transistor is configured as a control electrode to receive data signals, and the light shielding layer is configured as a bias electrode.

2. The display apparatus according to claim 1, wherein, when the first capacitance is smaller than the second capacitance, the light shielding layer in the second transistor is configured as a bias electrode to receive bias signals, and the top electrode of the second transistor is configured as a control electrode; when the first capacitance is larger than the second capacitance, the top electrode in the second transistor is configured as a bias electrode to receive bias signa, and the light shielding layer of the second transistor is configured as a control electrode.

3. The display apparatus according to claim 1, wherein, the light shielding layer in the second transistor is electrically connected to its top electrode and the light shielding layer are jointly configured as a control electrode of the second transistor.

4. The display apparatus according to claim 1, wherein the first transistor is a driving transistor, the second transistor is a switching transistor.

5. The display apparatus according to claim 1, wherein the first semiconductor layer comprises metal oxide semiconductor.

6. The display apparatus according to claim 1, wherein the second capacitance is 2-4 times of the first capacitance.

7. The display apparatus according to claim 1, wherein thickness of the first dielectric layer and thickness of the second dielectric layer are different, but dielectric constants of the two layers are the same; or, thickness of the first dielectric layer and thickness of the second dielectric layer are the same, but dielectric constant of the first dielectric layer and dielectric constant of the second dielectric layer are different; or, thickness of the first dielectric layer and thickness of the second dielectric layer are different, and their dielectric constants are also different.

8. A method of manufacturing method of a display apparatus, comprising
forming a first conductive layer on a substrate, and patterning the first conductive layer to form light shielding layers which are separated from each other;
forming a first dielectric layer on the substrate and the light shielding layer;
forming a first semiconductor layer on the first dielectric layer and patterning the first semiconductor layer to obtain separated active layers, and removing the active layer above part of the light shielding layers;
forming a second dielectric layer on the active layer and the first dielectric layer;
forming a second conductive layer on the second dielectric layer;
patterning the second conductive layer and the second dielectric layer so as to form separated top electrode layers and second dielectric layers, and removing the second conductive layer and the second dielectric layer above the part of the light shielding layers;
using the separated top electrode layers and second dielectric layers as a mask to form a source region and a drain region in the active layer located at either side of the top electrode layers;
forming a passivation layer on the top electrode layers, the active layers and the first dielectric layer;
wherein, a first capacitance formed between the light shielding layer and the active layer and a second capacitance formed between the active layer and the top electrode layer are different in value;
when the first capacitance is smaller than the second capacitance, the light shielding layer in the first transistor is configured as a control electrode to receive data signals, and the top electrode layer thereof is configured as a bias electrode to receive bias signals; when the first capacitance is larger than the second capacitance, the top electrode layer in the first transistor is configured as a control electrode to receive data signals, and the light shielding layer is configured as a bias electrode to receive bias signals.

9. The method according to claim 8, further comprising
forming vias in the passivation layer, and respectively forming above the passivation layer a first portion of a third conductive layer electrically connected to the top electrode layers, a second portion of the third conductive layer electrically connected to the source regions, and a third portion of the third conductive layer electrically connected to the light shielding layers;
patterning the third conductive layer to electrically isolate the first portion, the second portion, and the third portion of the third conductive layer in the first transistor.

10. The method according to claim 9, wherein patterning the third conductive layer comprises maintaining the electrical connection between the first portion and the third portion of the third conductive layer in the second transistor.

11. The method according claim 9, wherein when the first capacitance is smaller than the second capacitance, patterning the third conductive layer comprises, maintaining the electrical connection between the second portion and the third portion of the third conductive layer in the second transistor; when the first capacitance is larger than the second capacitance, patterning the third conductive layer comprises, maintaining the electrical connection of between the second portion and the first portion of the third conductive layer in the second transistor.

12. A display apparatus, comprising a pixel array, and a source driving circuit and a gate driving circuit coupled to the pixel array; wherein at least one pixel in said the pixel array comprises a third transistor and a fourth transistor formed on a same substrate and uniformly manufactured using the same process;
wherein the third transistor and the fourth transistor both comprise, the substrate;
a bottom electrode comprising a fourth conductive layer located on the substrate;
a third dielectric layer located on the bottom electrode;
an active layer comprising a second semiconductor layer located on the third dielectric layer, and a source region and a drain region located at two ends in the active layer;
a source electrode and a drain electrode comprising a fifth conductive layer which are respectively electrically connected to the source region and the drain region and are located on the active layer and the third dielectric layer;
a fourth dielectric layer comprising vias located on the active layer, the source electrode and the drain electrode and the third dielectric layer;
a light shielding layer located on the fourth dielectric layer and at least located above the active layer, comprising a sixth conductive layer;
wherein a third capacitance formed between the sixth conductive layer and the active layer and a fourth capacitance formed between the active layer and the bottom electrode are different in value;
when the third capacitance is smaller than the fourth capacitance, the light shielding layer in the third transistor is configured as a control electrode to receive data signals, and the bottom electrode thereof is configured as a bias electrode to receive bias signals; when the third capacitance is larger than the fourth capacitance, the bottom electrode in the third transistor is configured as a control electrode to receive data signals, and the light shielding layer is configured as a bias electrode to receive bias signals.

13. The display apparatus according to claim 12, wherein when the third capacitance is smaller than the fourth capacitance, the light shielding layer in the fourth transistor is configured as a bias electrode to receive bias signals, and the bottom electrode is configured as a control electrode; when the third capacitance is larger than the fourth capacitance, the bottom electrode in the fourth transistor is configured as a bias electrode to receive bias signals, and the light shielding layer is configured as a control electrode.

14. The display apparatus according to claim 12, wherein the light shielding layer of the fourth transistor is electrically connected to the bottom electrode are jointly configured as a control electrode of the second transistor.

15. The display apparatus according to claim 12, wherein the third transistor is a driving transistor, the fourth transistor is a switching transistor.

16. The display apparatus according to claim 12, wherein the second semiconductor layer comprises metal oxide semiconductor.

17. The display apparatus according to claim 12, wherein the fourth capacitance is 2-4 times of the third capacitance.

18. The display apparatus according to claim 12, wherein the thickness of the third dielectric layer and the thickness of the fourth dielectric layer are different, but the dielectric constants of the two layers are the same; or, the thickness of the third dielectric layer and the thickness of the fourth dielectric layer are the same, but the dielectric constant of the third dielectric layer and the dielectric constant of the fourth dielectric layer are different; or, the thickness of the third dielectric layer and the thickness of the fourth dielectric layer are different, and the dielectric constants are also different.

19. A manufacturing method of a display apparatus, comprising
forming a fourth conductive layer on a substrate, and patterning the fourth conductive layer to form separated bottom electrode layers;
forming a third dielectric layer on the substrate and the bottom electrode layers, and forming first vias in the third dielectric layer on some of the bottom electrode layers to expose a part of such bottom electrode layers;
forming a second semiconductor layer on the third dielectric layer, patterning the second semiconductor layer to form separated active layers which are doped to form source regions and drain regions, and removing the active layer in the first vias to expose the part of the bottom electrode layers;
forming a fifth conductive layer on the active layer, and patterning the fifth conductive layer, forming a source electrode layer and a drain electrode layer that are respectively and electrically connected with the source regions and the drain regions in the active layer;
forming a fourth dielectric layer on the active layer, the source electrode layer, the drain electrode layer and the third dielectric layer;
etching the fourth dielectric layer to form second vias exposing the source electrode layer, and removing the fourth dielectric layer in the first vias to expose a part of the bottom electrode layers;
forming a sixth conductive layer at least located above the active layer on the fourth dielectric layer;
patterning the sixth conductive layer to form separated light shielding layers, wherein the light shielding layers electrically connected to the source electrode layers through the second vias, the light shielding layers electrically connected to the bottom electrode layers through the first vias, and the rest light shielding layers are separated;
wherein, a third capacitance formed between the light shielding layers and the active layers and a fourth capacitance formed between the active layers and the bottom electrode layers are different in value;
when the third capacitance is smaller than the fourth capacitance, the light shielding layer in a third transistor is configured as a control electrode to receive data signals, and the bottom electrode thereof is configured as a bias electrode to receive bias signals; when the third capacitance is larger than the fourth capacitance, the bottom electrode in a third transistor is configured as a control electrode to receive data signals, and the light shielding layer is configured as a bias electrode to receive bias signals.

20. The method according to claim 19, wherein patterning the sixth conductive layer comprises respectively forming a first portion of the sixth conductive layer electrically connected to the bottom electrode layers through the first via, a second portion of the sixth conductive layer electrically connected to the source electrode layers through the second via, and a third portion of the sixth conductive layer electrically isolated from both the bottom electrode layers and the source and drain electrode layers; the light shielding layer in a third transistor is the third portion of the sixth conductive layer.

21. The method according to claim 20, wherein when the third capacitance is smaller than the fourth capacitance, patterning the sixth conductive layer comprises, the light shielding layer in a fourth transistor being the second portion of the sixth conductive layer; when the third capacitance is larger than the fourth capacitance, electrically connecting the bottom electrode layer of the second transistor to the source electrode layer.

22. The method according to claim 20, wherein the light shielding layer in the second transistor is the first portion of the sixth conductive layer.
